(19) United States
(12) Patent Application Publication
(10) Pub. No.: US 2009/0166060 A1
(43) Pub. Date: Jul. 2, 2009

(54) Insulating Resin Layer, Insulating Resin Layer With Carrier And Multiple-Layered Printed Wiring Board

(76) Inventors: Iji Onozuka, Tokyo (JP); Masataka Arai, Tokyo (JP); Takeshi Hosomi, Tokyo (JP)

Correspondence Address: SMITH, GAMBRELL & RUSSELL, 1130 CONNECTICUT AVENUE, N.W., SUITE 1130, WASHINGTON, DC, 20036, US

(21) Appl. No.: 12/225,106

(22) PCT Filed: Mar. 20, 2006
(86) PCT No.: PCT/JP2006/305548

§ 371 Date: Sep. 15, 2008

(51) Int. Cl. H05K 1/00; B32B 27/06

(52) U.S. Cl. 174/250; 428/411.1; 428/500; 428/424.8

(57) ABSTRACT

An insulating resin layer, which is capable of being employed for forming a multiple-layered printed wiring board via a thermal compression forming process, comprising: at least one first layer and at least one second layer being stacked, wherein a specific dielectric constant of the first layer at a frequency of 1 MHz after the thermal compression forming is not more than 3.2, and wherein a linear expansion coefficient of the second layer at a temperature within a range of from not lower than 35 degree C. to not higher than 85 degree C. after the thermal compression forming is not more than 40 ppm/degree C. A multiple-layered printed wiring board, formed by disposing the aforementioned insulating resin layer over at least one side of an internal layer circuit board, and then conducting a thermal compression forming process.

### TECHNICAL FIELD

The present invention relates to an insulating resin layer, an insulating resin layer with a carrier and a multiple-layered printed wiring board.

### RELATED ART

As an increase in capacity, an increase in operation speed, an increase in high-density arrangement and an increase in miniaturization are progressed in electronic equipments in recent years, a technique of mounting components having a plurality of functions in the surface of a single package substrate is often employed. However, such technique of mounting the components in the surface of the package substrate can utilize only a two-dimensional plane, which leads to a barrier for reducing dimensional area of the substrate to be smaller than the dimensional area of the components mounted therein, and thus an increase in high-density arrangement is strictly limited in such technique.

To solve the problem, an approach for spatially arranging and mounting the respective components in the inside of the substrate, in addition to the surface of the package substrate, to achieve a miniaturization and a high-density arrangement of the package substrate, is proposed.

It is known that an enhancement in a signal propagation rate is required for a substrate of a form having components mounted in the inside thereof in order to apply high-frequency operation of the components, and it is also known that, in order to satisfy such requirement, insulating resin layers having characteristics of lower dielectric constant, lower dielectric loss tangent and lower water absorption are required.

A typical resin exhibiting lower water absorption and higher dielectric characteristic is benzocyclobutene resin (see, for example, Patent Document 1). Since a functional group having higher polarizability such as hydroxyl group and the like is not generated by a curing reaction for benzocyclobutene resin, the resin exhibits lower water absorption and significantly improved dielectric characteristic. However, since a cured material of a benzocyclobutene resin is fragile due to its resin skeleton structure and thus its mechanical strength causes a problem, a crack is generated in cooling-heating cycles, depending on types of substrate structures, when it is employed with a metallic material having smaller linear expansion coefficient such as silicon or copper, and a problem in reliability in thermal environment may be caused.

In order to prevent a crack generated in the cooling-heating cycles, sufficient mechanical strengths such as lower linear expansion, higher tensile-strength and the like are required. In order to obtain such sufficient mechanical strengths, a method of, for example, employing a resin composition containing an inorganic filler at higher filler-loading, may be utilized (see, for example, Patent Document 2). Since an use of a resin composition containing an inorganic filler at higher filler-loading provides a reduced linear expansion coefficient and an enhanced tensile strength, a stress generated in cooling-heating cycles can be reduced to avoid a generation of a crack. However, higher loading of an inorganic filler in a resin composition causes higher dielectric constant, adversely affecting a signal propagation rate, which is considered to be critical for applications at high frequency.

Besides, cyanate resin is employed for a resin that exhibits lower linear expansion coefficient and higher mechanical strength. Curing reaction of cyanate resin creates triazine ring. Since triazine ring is rigid due to its skeleton structure, a volumetric change in thermal process is smaller and higher mechanical strength is achieved. However, since lone electron pair is present in atomic nitrogen in triazine ring, higher water absorption is concerned, and deterioration in specific dielectric constant and dielectric dissipation factor, which are considered to be critical for applications at high frequency under acid condition and in particular under high-temperature and high-humidity conditions, is concerned.

As described above, an insulating resin layer material, which is suitable for miniaturizations of package substrates and high-density arrangement, is capable of being adopted for multiple-layered printed wiring boards having components mounted therein, and has sufficient mechanical characteristics and dielectric characteristics, is required.

### [Patent Document 1]

### Japanese Patent Laid-Open No. 2000-21,872

### [Patent Document 2]

Japanese Patent Laid-Open No. H11-220,262 (1999)

### DISCLOSURE OF THE INVENTION

The present invention is directed to provide an insulating resin layer with higher mechanical strength and improved dielectric characteristic, such insulating resin layer with carrier, and a multiple-layered printed wiring board employing such resins.

The above-described purposes can be satisfied by the following configurations (1) to (8) of the present invention.

(1) An insulating resin layer, which is capable of being employed for forming a multiple-layered printed wiring board by a thermal compression forming process, comprising:

at least one first layer and at least one second layer being stacked,

wherein a specific dielectric constant of said first layer at a frequency of 1 MHz after the thermal compression forming is not more than 3.2, and

wherein a linear expansion coefficient of said second layer at a temperature within a range of from not lower than 35 degree C. to not higher than 85 degree C. after the thermal compression forming is not more than 40 ppm/degree C.

(2) The insulating resin layer as set forth in the above-described (1), wherein a water absorption of said first layer is not more than 0.8 wt %

(3) The insulating resin layer as set forth in the above-described (1) or (2), wherein a tensile strength of said second layer is not less than 80 MPa.

(4) The insulating resin layer as set forth in any one of the above-described (1) to (3), wherein said first layer contains benzocyclobutene resin and/or a prepolymer thereof.

(5) The insulating resin layer as set forth in any one of the above-described (1) to (4), wherein said second layer contains a cyanate resin and/or a prepolymer thereof.

(6) An insulating resin layer with a carrier, comprising: the insulating resin layer as set forth in any one of the above-described (1) to (5); and a carrier joined to at least one side thereof.

(7) A multiple-layered printed wiring board, formed by disposing the insulating resin layer as set forth in any one of the above-described (1) to (5) over at least one side of an internal layer circuit board, and then conducting a thermal compression forming process.

(8) A multiple-layered printed wiring board, formed by disposing the insulating resin layer as set forth in the above-described (6) over at least one side of an internal layer circuit board, and then conducting a thermal compression forming process.

The insulating resin layer of the present invention is employed for forming a multiple-layered printed wiring board by a thermal compression forming process. After the thermal compression forming process, the first and the second layers exhibit the following physical properties:

(i) a specific dielectric constant of the first layer at a frequency of 1 MHz is not more than 3.2; and

(ii) a linear expansion coefficient of the second layer at a temperature within a range of from not lower than 35 degree C. to not higher than 85 degree C. is not more than 40 ppm/degree C.

Conditions for the thermal compression forming process may be suitably selected.

In the present invention, it is preferable to satisfy the physical properties of the above-described (i) and (ii) after it is thermally cured under the conditions at 170 degree C. for one hour and at 200 degree C. for two hours. Having such configuration, a multiple-layered printed wiring board, which exhibits further improved mechanical strengths in the peripheral of the components as compared with the conventional technology, can stably be obtained without deteriorating the dielectric characteristics in the peripheral of the high frequency circuits.

The present invention is directed to an insulating resin layer having at least one resin layer exhibiting improved dielectric characteristics and at least one resin layer exhibiting improved mechanical characteristics, to such insulating resin layer with a carrier, and to a multiple-layered printed wiring board having thereof, and a multiple-layered printed wiring board having improved mechanical strengths in the peripheral of the components can be manufactured, as compared with the conventional technology, without deteriorating the dielectric characteristics in the peripheral of the high frequency circuits.

The insulating resin layer of the present invention exhibits enhanced mechanical strengths and improved dielectric characteristics, and a multiple-layered printed wiring board having improved mechanical strengths in the peripheral of the components can be manufactured, as compared with the conventional technology, without deteriorating the dielectric characteristics in the peripheral of the high frequency circuits. Therefore, the insulating resin layer of the present invention is suitable for miniaturizations of package substrates and high density arrangement, and is capable of being preferably adopted for multiple-layered printed wiring boards having components mounted therein. The multiple-layered printed wiring board of the present invention can be, in particular, preferably adopted for applications that require miniaturization, high density arrangement and enhanced properties such as a circuit board for a small data processing apparatus and the like.

### BEST MODE FOR CARRYING OUT THE INVENTION

Insulating resin layers, insulating resin layers with carriers and multiple-layered printed wiring boards of the present invention will be described as follows. The insulating resin layer (insulating resin film) of the present invention is employed for forming a multiple-layered printed wiring board by a thermal compression forming process, and is configured to comprise at least one first layer and at least one second layer being stacked, and is also configured that a specific dielectric constant of said first layer at a frequency of 1 MHz after a thermal compression forming is not more than 3.2, and a linear expansion coefficient of said second layer at a temperature within a range of from not lower than 35 degree C. to not higher than 85 degree C. after a thermal compression forming is not more than 40 ppm/degree C. In addition, the insulating resin layer with the carrier (insulating resin film with carrier) of the present invention is configured to comprise the above-described insulating resin layer of the present invention and a carrier joined to at least one side thereof. Further, the multiple-layered printed wiring board of the present invention is configured to be formed by disposing the above-described insulating resin layer or the insulating resin layer with the carrier of the present invention on at least one side of an internal layer circuit board, and then conducting a thermal compression forming thereof.

First of all, the insulating resin layer of the present invention will be described. The insulating resin layer of the present invention is employed for forming a multiple-layered printed wiring board by a thermal compression forming process, and comprises at least one first layer and at least one second layer being stacked. The first and the second layers after the thermal compression forming process exhibit the following physical properties. The first layer exhibits a specific dielectric constant at a frequency of 1 MHz of not more than 3.2, and in particular, the desirable specific dielectric constant is not more than 2.8. This allows reducing a loss of electrical signal due to a speedup of electrical signal or due to a microminiaturization in widths between electric circuit lines. Further, a water absorption of the first layer is preferably not more than 0.8 wt %, though it is not particularly limited. It is further preferable that the water absorption is not more than 0.4 wt % This allows maintaining a specific dielectric constant and a dielectric dissipation factor to be lower, which are critical for high frequency circuits, in particular in high temperature and high humidity conditions, thereby inhibiting a degradation of coupling reliability.

The resin composition, which can form the first layer, preferably contains benzocyclobutene resin and/or a prepolymer thereof, though it is not particularly limited thereto.

The benzocyclobutene resin available in the present invention is not particularly limited to any specific resin, and may be a resin having cyclobutene skeleton. Among these, it is preferable to contain any one of benzocyclobutene resin represented by the following general formula (I). This allows providing higher glass transition temperature, thereby providing an improved characteristic of a cured resin.

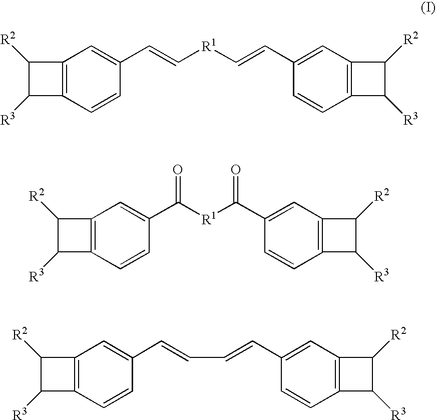

In the general formula (I), R¹ is an aliphatic group, an aromatic group, a hetero atom or the like or a combination thereof. R² and R³ are a hydrogen atom, an aliphatic group, an aromatic group, a hetero atom or the like or a combination thereof.

Since benzocyclobutene resin generates no functional group of higher polarizability such as hydroxyl group and the like by a curing reaction, significantly improved dielectric characteristic and lower water absorption are achieved. Further, a rigid chemical structure provides an improved heat resistance.

Further, a B-stage material (prepolymer) of benzocyclobutene resin having the above-described general formula (I) may also be preferably employed for suitably adjusting a moldability and a flowability, and thus is included in the present invention. A process for obtaining a B-stage material is ordinarily conducted by thermally melting benzocyclobutene resin. Here, a B-stage material of benzocyclobutene resin is one having a weight-average molecular weight of, for example, 3000 to more 1,000,000. The weight-average molecular weight may be measured by, for example a gel permeation chromatography (GPC, reference material: polystyrene conversion).

When benzocyclobutene resin is employed for a resin composition for forming the first layer, the content of benzocyclobutene resin in the resin composition may be preferably not less than 20 wt % to not more than 95 wt % for the whole solid content in the resin composition, and may be more preferably not less than 30 wt % to not more than 90 wt %, though is not particularly limited thereto. The content of lower than the above-described lower limit may cause insufficient effects for improving dielectric characteristics such as a specific dielectric constant, a dielectric dissipation factor and the like, and the content of higher than the above-described upper limit may cause a deterioration in mechanical strengths.

The second layer after the thermal compression forming process exhibits a linear-expansion coefficient at a temperature within a range from of not lower than 35 degree C. to not higher than 85 degree C. of not more than 40 ppm/degree C. In particular, linear expansion coefficient at temperature within a range of from not lower than 35 degree C. to not higher than 85 degree C. is preferably not more than 30 ppm/degree C. This allows reducing a dynamic strain generated in the insulating resin layer around metallic components such as chips, copper interconnects and the like, when a dynamic load is provided by a cooling-heating cycle test for not lower than −65 degree C. to not higher than 125 degree C. Here, a value of linear expansion coefficient may be in a range of not more than a glass transition temperature, in a case of an insulating resin layer having a glass transition temperature of not lower than 125 degree C. Further, the reason of employing a temperature within a range of from not lower than 35 degree C. to not higher than 85 degree C. is a convenience of the measurements that, if the temperature is lower than 35 degree C., the value of the linear expansion coefficient is lower, creating larger error in the measurement, and if the temperature is higher than 85 degree C., such temperature is closer to its glass transition temperature depending on the insulating resin layer, leading to a rapid increase in the linear expansion coefficient, eventually increasing difficulty in the precise measurement. Further, the tensile strength of the second layer is preferably not less than 80 MPa, and more preferably not less than 85 MPa, though is not particularly limited thereto. This allows reducing a crack generated in the insulating resin layer around metallic components such as chips, copper interconnects and the like due to dynamic strain generated by providing load of cooling-heating cycle, achieving an enhanced reliability in a thermal environment.

The resin composition that may compose such second layer preferably contain a cyanate resin and/or a prepolymer thereof, though is not particularly limited thereto.

The cyanate resin may be a resin having cyanate group, though is not particularly limited thereto. The aforementioned cyanate resin may be obtained by reacting, for example, a halogenated cyanide with phenol, and then heating thereof as required to achieve a pre-polymerization. More specifically, typical cyanate resin may include bisphenolic cyanate resins such as novolac cyanate resins, bisphenol A based cyanate resins, bisphenol E based cyanate resins, tetramethyl bisphenol F based cyanate resins and the like. Among these, novolac cyanate resins represented by the following general formula (II) are preferable. This provides an improved heat resistance by increasing cross linking density, and in turn an improved fire retardancy of the resin compositions. This is because novolac cyanate resin contains triazine ring after the curing reaction. Further, it is further considered that this is also because novolac cyanate resin has benzene ring at higher content ratio for its structural reason and thus is easy to be carbonized.

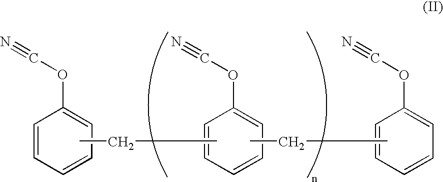

In the general formula (II), n is any integer number.

The cyanate resin creates triazine ring by the curing reaction, and exhibits an improved heat resistance due to its rigid skeleton structure, and further exhibits smaller volume change in the thermal processing, and thus exhibits an improved mechanical strengths.

Average number “n” of repeating units of novolac cyanate resin represented by the aforementioned formula (II) may be preferably 1 to 10, and more preferably 2 to 7, though is not particularly limited thereto. If the average number “n” of repeating units is lower than the above-described lower limit, the novolac cyanate resin is easily crystallized to relatively deteriorate a solubility thereof for a general purpose solvent, possibly causing a difficulty in the handling. Further, if the average number “n” of repeating units is higher than the aforementioned upper limit, the melt viscosity is excessively increased, possibly deteriorating a moldability of the insulating resin layer.

The weight-average molecular weight of the novolac cyanate resin represented by the above-described general formula (II) is preferably 500 to 4,500, and more preferably 600 to 3,000, though is not particularly limited thereto. The weight-average molecular weight of the novolac cyanate resin of lower than the above-described lower limit may lead to a deterioration of the mechanical strengths of the cured material of the insulating resin layer, a tackiness may be caused and a transfer of the resin may be caused when the insulating resin layer is further manufactured. On the other hands, the molecular weight of higher than the above-described upper limit may lead to faster curing reaction, so that a molding failure may be generated, or an inter-layer peeling strength may be deteriorated, when it is employed for forming a substrate (in particular, circuit board). The weight-average molecular weight of the aforementioned novolac cyanate resin may be measured by, for example a gel permeation chromatography (GPC, reference material: polystyrene conversion).

When a cyanate resin is employed in a resin composition for forming the second layer, the content of the cyanate resin in a resin composition is preferably 5 to 60 wt % of the whole solid content in the resin composition, and more preferably 10 to 50 wt %, though is not particularly limited thereto. The content of lower than the above-described lower limit may lead to a deteriorated effect for improving the mechanical strengths, and the content of higher than the above-described upper limit may lead to an increased water absorption, deteriorating the dielectric characteristics in high frequency area.

When a cyanate resin (in particular novolac cyanate resin) is employed in a resin composition for forming the aforementioned second layer, it is preferable to also additionally employ an epoxy resin (containing substantially no halogen atom). Typical example of the aforementioned epoxy resins may include, for example: bisphenolic based epoxy resins such as bisphenol A based epoxy resin, bisphenol F based epoxy resin, bisphenol E based epoxy resin, bisphenol S based epoxy resin, bisphenol Z based epoxy resin, bisphenol P based epoxy resin, bisphenol M based epoxy resin and the like; novolac epoxy resins such as phenolic novolac based epoxy resin, creosol novolac based epoxy resin and the like; aryl alkylene based epoxy resins such as biphenyl based epoxy resin, xylylene based epoxy resin, biphenyl aralkyl based epoxy resin and the like; naphthalene based epoxy resin; anthracene based epoxy resin; phenoxy based epoxy resin; dicyclopenta diene based epoxy resin; norbornene based epoxy resin; adamantane based epoxy resin; fluorene based epoxy resin, and the like. One of these epoxy resins may be employed alone, or two or more of these epoxy resins having different weight-average molecular weights may also be employed, or a combination of one, two or more of these epoxy resins and a prepolymer thereof may also be employed. Among these epoxy resins, aryl alkylene based epoxy resin is particularly preferable. This allows achieving an improved solder heat resistance after moisture absorption and an improved fire retardancy.

The aforementioned aryl alkylene based epoxy resin is an epoxy resin having one or more aryl alkylene group in its repeating unit. This includes, for example, xylylene based epoxy resin, biphenyl dimethylene based epoxy resin and the like. Among these, biphenyl dimethylene based epoxy resin is preferable. Biphenyl dimethylene based epoxy resin may be represented by, for example, the formula (III).

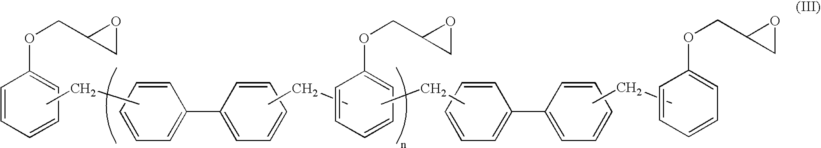

In the general formula (III), n is any integer number.

The average number “n” of repeating units of biphenyl dimethylene based epoxy resin represented by the aforementioned formula (III) is preferably 1 to 10, and more preferably 2 to 5, though is not particularly limited thereto. If the average number “n” of repeating units is lower than the above-described lower limit, the biphenyl dimethylene based epoxy resin is easily crystallized to relatively deteriorate a solubility thereof for a general purpose solvent, possibly causing a difficulty in the handling. Further, if the average number “n” of repeating units is higher than the aforementioned upper limit, the flowability of the resin is deteriorated, possibly causing a molding failure. These characteristics can be well-balanced by specifying the average number “n” of repeating units within the above-described range.

The content of the aforementioned epoxy resin is preferably 1 to 55 wt % of the whole resin composition, and more preferably 5 to 40 wt %, though is not particularly limited thereto. If the content is lower than the above-described lower limit, the reactivity of cyanate resin may be deteriorated or a moisture resistance of the obtained product may be deteriorated, and if the content is higher than the above-described upper limit, the characteristics of lower thermal expansion and better heat resistance may be deteriorated.

The weight-average molecular weight of the aforementioned epoxy resin is preferably 500 to 20,000 for weight-average molecular weight, and more preferably 800 to 15,000, though is not particularly limited thereto. If the weight-average molecular weight is lower than the above-described lower limit, a tackiness may be caused on the surface of the insulating resin layer, and if the weight-average molecular weight is higher than the above-described upper limit, the solder heat resistance may be deteriorated. These characteristics can be well-balanced by specifying the weight-average molecular weight within the above-described range. The weight-average molecular weight of the aforementioned epoxy resin may be measured by, for example, GPC.

The resin composition of the present invention preferably contains a film-forming resin. This allows providing further improved film-formability and handling-ability in manufacturing the insulating resin layer with a base member.

Typical example of the above-described film-forming resin may include, for example, phenoxy based resin, bisphenol F based resin, olefin based resin and the like. One of the above-described film-forming resin and its derivatives may be employed alone, or two or more of those having different weight-average molecular weights may also be employed, or a combination of one, two or more of those and a prepolymer thereof may also be employed. Among these, phenoxy based resin is preferable. This allows providing an improved heat resistance and fire retardancy.

The above-described phenoxy based resin typically includes, for example: phenoxy resins having bisphenol skeleton such as phenoxy resin having bisphenol A skeleton, phenoxy resin having bisphenol F skeleton, phenoxy resin having bisphenol S skeleton, phenoxy resin having bisphenol M skeleton, phenoxy resin having bisphenol P skeleton, phenoxy resin having bisphenol Z skeleton and the like; phenoxy resin having novolac skeleton; phenoxy resin having anthracene skeleton; phenoxy resin having fluorene skeleton; phenoxy resin having dicyclopenta diene skeleton; phenoxy resin having norbornene skeleton; phenoxy resin having naphthalene skeleton; phenoxy resin having biphenyl skeleton; phenoxy resin having adamantane skeleton and the like, though is not particularly limited thereto. In addition, a structure of phenoxy resin having two or more of these skeletons may be employed, or phenoxy resins having skeletons of different content ratios may be employed. Further, multiple types of phenoxy resins having different skeletons may be employed, or multiple type of phenoxy resins having different weight-average molecular weights may be employed or prepolymers thereof may also be additionally employed.

Among these, phenoxy resin having biphenyl skeleton and bisphenol S skeleton may be employed. This allows providing higher glass transition temperature due to structural inflexibility of biphenyl skeleton, and also providing an improved adhesiveness of a plating metal in manufacturing a multiple-layered printed wiring board due to a presence of bisphenol S skeleton. Alternatively, phenoxy resin having bisphenol A skeleton and bisphenol F skeleton may be employed. This allows providing an improved adhesiveness to an internal layer circuit board in manufacturing a multiple-layered printed wiring board. Further, a combination of the above-described phenoxy resin having biphenyl skeleton and bisphenol S skeleton and the above-described phenoxy resin having bisphenol A skeleton and bisphenol F skeleton may be employed.

The molecular weight of the above-described film-forming resin may preferably be 1000 to 100,000, though is not particularly limited thereto. More preferably, it may be 10,000 to 60,000. If the weight-average molecular weight of the film-forming resin is lower than the above-described lower limit, the effect of improving the film-formability may not be sufficient. On the contrary, the weight-average molecular weight of higher than the above-described upper limit may lead to a decreased solubility of the film-forming resin. These characteristics can be well-balanced by specifying the weight-average molecular weight of the film-forming resin within the above-described range.

The content of the film-forming resin may be preferably 1 to 40 wt % of the whole resin composition, and more preferably 5 to 30 wt %, though is not particularly limited thereto. The content of the film-forming resin of lower than the above-described lower limit may lead to insufficient effect of improving the film-formability. On the contrary, the content of higher than the above-described upper limit may lead to relatively reduced content of cyanate resin, deteriorating the effect for providing a reduced thermal expansion. These characteristics can be well-balanced by specifying the content of the film-forming resin within the above-described range.

Both of the above-described thermosetting resin employed in the composition of the present invention and the film-forming resin preferably contain substantially no halogen atom. This allows providing fire retardancy without employing a halogen compound. Here, “contain substantially no halogen atom” means, for example, a content of halogen atom in epoxy resin or in phenoxy resin of not more than 0.15 wt % (JPCA-ES01-2003).

Here, specific dielectric constant, water absorption, linear expansion coefficient and tensile strength in the present invention were measured by the following conditions, respectively.

(1) Specific dielectric constant: it was measured based on JIS C 6481 under “A” condition at a frequency of 1 MHz.

(2) Water absorption: it was measured based on JIS C 6481 under the conditions of E-24/50+D-24/23.

(3) Linear expansion coefficient: it was measured for Ramp rate of 10 degree C., and from not lower than 35 degree C. to not higher than 85 degree C.

(4) Tensile strength: it was measured in tensile mode under load full scale of 20 kgf at a pulling speed of 5 mm/min.

In the insulating resin layer of the present invention, the resin compositions for forming the above-described first layer and the second layer may contain curing agents, respectively.

A curing agent may be employed as required for a resin composition for forming the first layer. Although the available curing agent is not particularly limited, when benzocyclobutene resin is employed, a curing agent for such compound or a compound functioning as an equivalent of such curing agent may include, for example: chemical compounds having olefin as functional group such as triaryl isocyanurate, polybutadiene rubber, styrene butadiene rubber (SBR), nitrile butadiene rubber (NBR), acrylonitrile butadiene styrene (ABS) and the like; chemical compounds having acrylic as functional group such as acrylic ester and the like; chemical compounds having functional group of methacrylic such as methyl methacrylate (MMA) and the like; chemical compounds having azido group such as 1,2-bis(azidobenzyl)ethylene, 2,6-di-(para azide benzal)-4-ethyl cyclohexanone and the like. One compound in these chemical compounds and derivatives thereof may be employed alone for a curing agent, or two or more compounds in these chemical compounds and derivatives thereof may also be employed.

In addition, a curing agent may be employed as required for a resin composition for forming the second layer. Although the available curing agent is not particularly limited, when cyanate resin is employed, a curing agent for such compound or a compound functioning as an equivalent of such curing agent may include, for example: imidazole compounds such as 1-benzil-2-methyl imidazole, 1-benzil-2-phenylimidazole, 2-phenyl-4-methyl imidazole, 2-ethyl-4-methyl imidazole, 2,4-diamino-6-[2′-methyl imidazolyl-(1′)]-ethyl-s-triazine, 2,4-diamino-6-(2′-undecyl imidazolyl)-ethyl-s-triazine, 2,4-diamino-6-[2′-ethyl-4-methyl imidazolyl-(1′)]-ethyl-s-triazine, 2-phenyl-4,5-dihydroxymethyl imidazole, 2-phenyl-4-methyl-5-hydroxymethyl imidazole and the like; organometallic salts such as zinc naphthenate, cobalt naphthenate, stannous octoate, cobalt octoate, bis acetylacetonato cobalt (II), tris acetylacetonato cobalt (III) and the like; tertiary amines such as triethyl amine, tributyl amine, diazabicyclo[2,2,2]octane and the like; phenolic compounds such as phenol, bisphenol A, nonylphenol and the like; organic acids such as acetic acid, benzoic acid, salicylic acid, para toluenesulfonic acid and the like; or a mixture thereof. One compound in these chemical compounds and derivatives thereof may be employed alone for a curing agent, or two or more compounds in these chemical compounds and derivatives thereof may also be employed.

Although the content of the curing agent is not particularly limited, when benzocyclobutene resin is employed for a resin composition for forming the first layer, the content may be preferably 0.1 to 5 wt %, in the benzocyclobutene resin, and more preferably 1 to 4 wt % In addition, when cyanate resin is employed for a resin composition for forming the second layer, for example, an imidazole compound may be preferably added to the cyanate resin at 0.01 to 1 wt %, and more preferably 0.02 to 0.8 wt % Alternatively, in the case of employing novolac phenolic resin, it may be preferably added to cyanate resin at 1 to 10 wt %, and more preferably 2 to 8 wt %

If the content of the curing agent in the resin composition for forming the first layer is lower than the above-described lower limit, a flow in thermal compression forming may be increased when a multiple-layered printed wiring board is manufactured, possibly deteriorating a smoothness of the insulating resin layer. On the contrary, if the content is higher than the above-described upper limit, a failure in the molding may be caused in the multiple-layered printed wiring board. If the content of the curing agent in the resin composition for forming the second layer is lower than the above-described lower limit, a flow in thermal compression forming may be increased to cause a variation in the thickness of the insulating layer, or the multiple-layered printed wiring board may be easily slipped in the thermal compression forming process. On the contrary, if the content is higher than the above-described upper limit, a failure in the molding may be caused in the multiple-layered printed wiring board.

In the resin composition for forming the insulating resin layer of the present invention, an inorganic filler may be employed for both of the first layer and the second layer. The inorganic filler available here may include, for example: silicates such as talc, burnt clay, non-burnt clay, mica, glass and the like; oxides such as titanium oxide, alumina, silica, fused silica and the like; carbonates such as calcium carbonate, magnesium carbonate, hydrotalcite and the like; hydroxides such as aluminum hydroxide, magnesium hydroxide, calcium hydroxide and the like; sulfates or sulfites such as barium sulfate, calcium sulfate, calcium sulfite and the like; borates such as zinc borate, barium metaborate, aluminum borate, calcium borate, sodium borate and the like; nitrides such as aluminum nitride, boron nitride, silicon nitride, carbon nitride and the like; titanates such as strontium titanate, barium titanate and the like, though is not particularly limited thereto. One of these inorganic fillers may be employed alone, or two or more of these inorganic fillers may also be employed.

Among these, silica, which exhibits a reduced thermal expansion and enhanced insulating reliability, is preferable. Further, spherical silica is preferable, and spherical fused silica is more preferable. This allows increasing the inorganic filler loading in the resin composition, particularly reducing the thermal expansion of the insulating resin layer. Additionally, since an use of the spherical silica allows maintaining lower melt viscosity of the resin composition, an improved moldability for filling the irregularity on the internal layer circuit board in the process for manufacturing the multiple-layered printed wiring board can be achieved.

The particle size of the above-described inorganic filler is preferably 0.01 to 5 μm as mean particle diameter, and more preferably 0.2 to 2 μm, though is not particularly limited thereto. The mean particle diameter of lower than the above-described lower limit may cause an increase in the viscosity when the resin composition varnish is prepared. On the contrary, the mean particle diameter of higher than the above-described upper limit may easily cause a sedimentation of the inorganic filler in the resin composition varnish, and thus both cases may lead to a decreased workability.

In the resin composition for forming the insulating resin layer of the present invention, a coupling agent may be employed for both of the first layer and the second layer. The aforementioned coupling agent serves as providing an improved wettability in an interface between the aforementioned thermosetting resin and the aforementioned inorganic filler, thereby providing an improved thermal resistance of, and in particular an improved thermal resistance of the moisture-absorbed solder. Any materials, which can be generally employed for coupling agents, may be employed for the aforementioned coupling agent, and more specifically, it is preferable to employ one or more coupling agent(s) selected from the group consisting of epoxy silane coupling agent, cationic silane coupling agent, amino silane coupling agent, titanate based coupling agent and silicone oil based coupling agent. This allows enhancing a wettability in the interface between the aforementioned thermosetting resin and the aforementioned inorganic filler, thereby providing further improved thermal resistance.

The resin compositions employed for the insulating resin layer of the present invention may further include, in addition to the constituents described above and without conflicting the purpose of the present invention, thermoplastic resins such as phenoxy resin, polyimide resin, polyamide imide resin, polyphenylene oxide resin, polyethersulfone resin, polyester resin, polyethylene resin, polystyrene resin and the like; polystyrene based thermoplastic elastomers such as styrene-butadiene copolymer, styrene-isoprene copolymer and the like; thermoplastic elastomers such as polyolefin based thermoplastic elastomer, polyamide based elastomer, polyester based elastomer and the like; diene based elastomers such as polybutadiene, epoxy-modified polybutadiene, acrylic-modified polybutadiene, methacrylic-modified polybutadiene and the like. Moreover, the aforementioned resin composition may further includes, in addition to the above-described constituents, additives such as a pigment, a dye, an antifoaming agent, a leveling agent, an ultraviolet absorber, a foaming agent, an antioxidant, a fire retardant agent, an ion scavenger and the like, as required.

The insulating resin layer of the present invention includes the first layer and the second layer, which are formed from such resin compositions. This allows achieving a good balance of a covering capability for irregularity of internal-layer circuits and mounted components with a maintenance of the thickness of the insulating layer and a smoothing in the manufacture of the multiple-layered printed wiring board.

The thickness of the first layer and the second layer In the insulating sheet of the present invention, is not particularly limited. and the first layer may be preferably 10 to 50 μm, and the second layer may be preferably 10 to 100 μm. Further, the thickness of the whole insulating sheet may be preferably 20 to 100 μm, though is not particularly limited thereto.

The insulating resin layer of the present invention is composed of the first layer and the second layer as described above, and respective one or more layers are deposited. The configuration of the insulating resin layer of the present invention is not particularly limited, and for example, a single first layer and a single second layer may be joined to present the insulating resin layer of the present invention. Further, two or more of the first layer and/or the second layer may alternatively be joined to provide the insulating resin layer of the present invention.

Next, the insulating resin layer with the carrier of the present invention will be described. The insulating resin layer with the carrier of the present invention is comprised of the insulating resin layer of the present invention as described above and a carrier joined to at least one side thereof.

Although a method for forming the insulating resin layer onto the carrier is not particularly limited, the method typically includes, for example: a method of dissolving and/or dispersing a resin composition in a solvent to prepare a resin varnish and coating the resin varnish over the carrier by using a suitable coating machine and then drying thereof; spray-coating the resin varnish over the carrier by using a spray equipment and then drying thereof, and the like. Among these, the method for coating the resin varnish over the carrier by employing suitable coater devices such as a comma bar coater, a die coater and the like and then drying thereof, may be preferable. This allows manufacturing the insulating resin layer with the carrier having the uniform thickness of the insulating resin layer without generating voids with an improved efficiency.

Available materials for the above-described carrier may include, for example: polyester resins such as polyethylene terephthalate, polybutylene terephthalate and the like; thermoplastic resin films having better thermal resistance such as fluorine based resin polyimide resin and the like; or foils of metals such as copper and/or copper based alloy, aluminum and/or aluminum based alloy, iron and/or iron based alloy, silver and/or silver based alloy, gold and gold based alloy, zinc and zinc based alloy, nickel and nickel based alloy, tin and tin based alloy and the like, though is not particularly limited thereto.

Although a positional relationship between the carrier and the insulating resin layer in the insulating resin layer with carrier of the present invention is not particularly limited, when, for example, the insulating resin layer is composed of a single one of the above-described first layer and a single one of the above-described second layer, it is preferable that the first layer is formed in the side that is joined to the carrier. It is also preferable that the second layer is formed in an opposite side to that joined to the carrier. In this configuration, the insulating resin layer with the carrier is disposed so that the side of the insulating resin layer in the insulating resin layer with the carrier is joined on the side of the internal layer circuit board or on the side of the internal layer circuit board side having mounted components, when the multiple-layered printed wiring board is manufactured by employing the insulating resin layer with the carrier of the present invention, and then a thermal compression forming process is conducted, such that a good balance can be achieved between the advantageous effects of a maintaining of the thickness of the insulating layer and a smoothing provided by the first layer and the advantageous effects of a better covering capability for irregularity of internal-layer circuits and mounted components provided by the second layer. Alternatively, two or more of the above-described first layer and/or the second layer may be employed and be joined with the carrier to provide the insulating resin layer with the carrier of the present invention.

Although a process for manufacturing the insulating resin layer and the insulating resin layer with the carrier of the present invention is not particularly limited to any specific process, typical process for forming thereof may include preparing a resin varnish by dissolving the resin compositions for forming the above-described first layer and the second layer in a solvent and coating thereof consecutively coating in a predetermined sequential order over the carrier by employing ordinary coating device. An use of the resin composition in a form of a resin varnish provides an improved coating-ability, so that an improved smoothness and an enhanced accuracy in the thickness of the insulating resin layer can be obtained. For example, the resin varnish for the first layer is applied over the carrier and is dried at a predetermined temperature (for example 80 to 200 degree C.) to substantially remove the solvent to form a film of the first layer, and then the resin varnish for the second layer is further applied and then a film of the second layer is formed in a similar process. Such process may be employed to obtain the insulating resin layer with the carrier. The obtained insulating resin layer with the carrier may be employed as it is, or the carrier may be detached to utilize the insulating resin layer itself.

Although the solvent employed for preparing the resin varnish for the above-described first layer and the second layer preferably exhibits better solubility for such resin compositions, a poor solvent may be employed provided that no harmful influence is exerted. Typical good solvent for benzocyclobutene resin may include toluene, xylene, mesitylene, cyclohexanone and the like, and typical good solvent for cyanate resin includes acetone, methyl ethyl ketone, methyl isobutyl ketone, cyclohexanone, tetrahydrofuran, dimethylformamide, dimethylacetamide, dimethylsulfoxide, ethylene glycol, cellosolve based solvents, carbitol based solvents and the like.

Next, the multiple-layered printed wiring board of the present invention will be described. The multiple-layered printed wiring board of the present invention may be obtained by disposing the insulating resin layer(s) or the insulating resin layer(s) with the carrier of the present invention obtained by the above-described procedure on one side or both sides of the internal layer circuit board and then conducting a thermal compression forming process. Although the available process for manufacturing the multiple-layered printed wiring board of the present invention is not particularly limited to any specific process, a process for, for example, temporarily compressively bonding respective one of, or two or more of, the first layer and the second layer, over the internal layer circuit board via a lamination or the like and then conducting a thermal compression forming process may be employed for manufacturing thereof, in addition to a process for disposing an insulating resin layer composed of two types of layers that are previously unified over the internal layer circuit board and then conducting a thermal compression forming process.

In addition to above, when the multiple-layered printed wiring board of the present invention is manufactured, it is preferable that the insulating resin layers is stacked so that the above-described second layer is located on the side of the internal layer circuit board or on the side of the internal layer circuit board side having mounted components and the first layer or a plurality of layers including the first layer is located on the opposing side, and then a thermal compression forming process is conducted. This allows achieving the effects of a maintenance of the thickness of the insulating layer and a smoothing by the first layer, and the effects of a covering capability for irregularity of internal-layer circuits and mounted components by the second layer. The temperature for the thermal process in the manufacture of the multiple-layered printed wiring board may be preferably not lower than 140 degree C. to not higher than 240 degree C., though is not particularly limited thereto. Further, the pressure for the thermal pressure may be preferably 1 to 4 MPa, though is not particularly limited thereto.

The multiple-layered printed wiring board of the present invention reduces a dynamic strain, which is generated when a cooling-heating cycle load is acted, by employing the insulating resin layer of the present invention, and an enhanced reliability in thermal environment can be achieved without deteriorating high frequency property by reducing a generation of a crack in the resin near the metallic material such as chip, copper interconnect and the like. This allows spatially arranging and mounting the components in the inside of the substrate to achieve a miniaturization and a high-density arrangement of the substrate.

### EXAMPLES

The present invention will be further described in reference to examples and comparative examples, through it is not intended that the present invention is limited thereto.

### Example 1

### 1. Preparation of Resin Varnish

### (1) Preparation of Resin Varnish for First Layer

The following components were dissolved in mesitylene at respective ratios over the solid content of the whole resin composition: 50 wt % of divinylsiloxane-bisbenzocyclobutene (B-stage material, weight-average molecular weight of 140,000, commercially available from Dow Chemical Japan, “CYCLOTENE XUR”) for benzocyclobutene resin; 10 wt % of acrylic-modified polybutadiene rubber (weight-average molecular weight of 2,800, commercially available from Osaka Organic Chemical Industry Co., Ltd., “BAC-45”) for liquid elastomer; and 2 wt % of 2,6-di-(para azide benzal)-4-ethyl cyclohexanone for curing agent, and further, 38 wt % of silica (commercially available from Admatechs Co., Ltd., “SO-25H”, mean particle diameter of 0.6 μm, maximum particle diameter of 5 μm) was added for inorganic filler and was dispersed to prepare the resin varnish for the first layer so that the non-volatile concentration is adjusted to be 50 wt %

### (2) Preparation of Resin Varnish for Second Layer

The following components are dissolved and dispersed in methyl ethyl ketone at respective ratios over the solid content of the whole resin composition: 25 wt % of novolac cyanate resin (commercially available from Lonza Japan Co., Ltd., “Primaset PT-30”, weight-average molecular weight of about 700); 24.7 wt % of biphenyl dimethylene based epoxy resin (commercially available from Nippon Kayaku Co., Ltd., “NC-3000”, weight per epoxy equivalent of 275, weight-average molecular weight of 2,000); 10 wt % of copolymer of phenoxy resin/biphenyl epoxy resin and bisphenol S epoxy resin, terminal part of which has epoxy group (commercially available from Japan Epoxy Resin Co., Ltd., “Yx-8100H30”, weight-average molecular weight of 30,000); and 0.1 wt % of imidazole compound (commercially available from Shikoku Chemicals Corporation, “Curezol 1B2PZ”, (1-benzil-2-phenylimidazole)). Further, 40 wt % of silica (commercially available from Admatechs Co., Ltd., “SO-25H”, mean particle diameter of 0.5 μm) for inorganic filler and 0.2 wt % of coupling agent/epoxy silane coupling agent (commercially available from GE Toshiba Silicone Co., Ltd., “A-187”) were added thereto, and then was stirred by employing a faster stirring device for ten minutes to prepare the resin varnish for the second layer so that the solid content is adjusted to be 50 wt %

### 2. Manufacture of Insulating Resin Layer with Carrier

The above-described resin varnish for the first layer was applied over a copper foil (thickness of 18 μm, commercially available from Furukawa Circuit Foil Co. Ltd.) to a thickness of 40 μm, and then was dried in a drying furnace at 150 degree C. for 10 minutes and in a drying furnace at 170 degree C. for 10 minutes to form the first layer having a thickness 20 μm. Subsequently, the resin varnish for the second layer was employed to similarly apply the varnish to a thickness of 120 μm, and then was dried in a drying furnace at 110 degree C. for 10 minutes and in a drying furnace at 150 degree C. for 10 minutes to form the second layer having a thickness 60 μm, and thus the insulating resin layer with the carrier having a total thickness of the insulating resin layer of 80 μm was manufactured.

### 3. Manufacture of Multiple-Layered Printed Wiring Board

A multiple-layered printed wiring board with double sided-copper claddings having a copper foil thickness of 18 μm with line width/line interval (L/S)=50/50 was utilized as a core (size: length of 4 cm, side of 4 cm, thickness of 0.6 mm), and a chip (size: length of 5 mm, side of 5 mm, thickness of 0.06 mm) was disposed on one side thereof, and each of both sides thereof was provided with the side of the insulating resin layer in the above-described insulating resin layer with the carrier, and then thermal pressure adhesion processes for such board were conducted at 170 degree C. for one hour and at 200 degree C. for two hours to thermally cure the materials, thereby forming the multiple-layered printed wiring board.

### 4. Manufacture of Insulating Resin Layer for Evaluation

The above-described resin varnish for the first layer was applied over a copper foil (thickness of 18 μm, commercially available from Furukawa Circuit Foil Co. Ltd.) to a thickness of 40 μm, and then was dried in a drying furnace at 150 degree C. for 10 minutes and in a drying furnace at 170 degree C. for 10 minutes to form the insulating resin layer with the carrier having a thickness 20 μm, and the obtained two insulating resin layers with the carrier were stacked and the carrier was detached, and then a thermal pressure adhesion process was conducted at 170 degree C. for one hour and at 200 degree C. for two hours to cause a thermal cure, thereby preparing an insulating resin layer (first layer) for evaluation having a thickness of 40 μm. Similarly, the above-described resin varnish for the second layer was applied over the copper foil (thickness of 18 μm, commercially available from Furukawa Circuit Foil Co. Ltd.) to a thickness of 120 μm, and then was dried in a drying furnace at 110 degree C. for 10 minutes and in a drying furnace at 150 degree C. for 10 minutes to form the insulating resin layer with the carrier having a thickness 60 μm, and the obtained two insulating resin layers with the carrier were stacked and the carrier was detached, and then a thermal pressure adhesion process was conducted at 170 degree C. for one hour and at 200 degree C. for two hours to cause a thermal cure, thereby preparing another insulating resin layer (second layer) for evaluation having a thickness of 120 μm.

### Example 2

### 1. Preparation of Resin Varnish

The resin varnish for the first layer and the resin varnish for the second layer were prepared similarly as in Example 1, except that the blending ratios for the resin varnish were selected as follows. The resin varnish for the first layer was prepared to include: 45 wt % of divinylsiloxane-bis benzocyclobutene resin (“CYCLOTENE XUR”); 15 wt % of acrylic-modified polybutadiene rubber (BAC-45); 2 wt % of 2,6-di-(para azide benzal)-4-ethyl cyclohexanone; and 38 wt % of silica (SO-25H). The resin varnish for the second layer was prepared to include: 29.1 wt % of novolac cyanate resin (Primaset PT-30); 28.8 wt % of biphenyl dimethylene based epoxy resin (NC-3000); 11.8 wt % of copolymer of phenoxy resin/biphenyl epoxy resin and bisphenol S epoxy resin, terminal part of which has epoxy group (YX-8100H30); 0.1 wt % of imidazole compound (Curezol 1B2PZ); 30 wt % of silica (SO-25H); and 0.2 wt % of epoxy silane coupling agent (A-187).

### 2. Manufacture of Insulating Resin Layer with Carrier

The insulating resin layer with the carrier having a total thickness of the insulating resin layers of 80 μm was manufactured similarly as in Example 1, except that the resin varnish for the first layer and the resin varnish for the second layer obtained as described above were employed.

### 3. Manufacture of Multiple-Layered Printed Wiring Board

The multiple-layered printed wiring board was manufactured similarly as in Example 1, except that the insulating resin layer with the carrier obtained above was employed.

### 4. Manufacture of Insulating Resin Layer for Evaluation

The insulating resin layers for evaluation (first layer, second layer) were manufactured similarly as in Example 1, except that the resin varnish for the first layer and the resin varnish for the second layer obtained above were employed.

### Example 3

### 1. Preparation of Resin Varnish

The resin varnish for the first layer and the resin varnish for the second layer were prepared similarly as in Example 1.

### 2. Manufacture of Insulating Resin Layer with Carrier

The above-described varnish for the first layer was applied over a copper foil (thickness of 18 μm, commercially available from Furukawa Circuit Foil Co. Ltd.) to a thickness of 20 μm, and then was dried in a drying furnace at 150 degree C. for 10 minutes and in a drying furnace at 170 degree C. for 10 minutes to form the first layer having a thickness 10 μm. Subsequently, the varnish for the second layer was employed to similarly apply the varnish to a thickness of 180 μm, and then was dried in a drying furnace at 110 degree C. for 10 minutes and in a drying furnace at 150 degree C. for 10 minutes to form the second layer having a thickness 90 μm, and thus the insulating resin layer with the carrier having a total thickness of the insulating resin layer of 100 μm was manufactured.

### 3. Manufacture of Multiple-Layered Printed Wiring Board

The multiple-layered printed wiring board was manufactured similarly as in Example 1, except that the insulating resin layer with the carrier obtained above was employed.

### 4. Manufacture of Insulating Resin Layer for Evaluation

The above-described resin varnish for the first layer was applied over a copper foil (thickness of 18 μm, commercially available from Furukawa Circuit Foil Co. Ltd.) to a thickness of 20 μm, and then was dried in a drying furnace at 150 degree C. for 10 minutes and in a drying furnace at 170 degree C. for 10 minutes to form the insulating resin layer with the carrier having a thickness 10 μm, and the obtained two insulating resin layers with the carrier were stacked and the carrier was detached, and then a thermal pressure adhesion process was conducted at 170 degree C. for one hour and at 200 degree C. for two hours to cause a thermal cure, thereby preparing an insulating resin layer (first layer) for evaluation having a thickness of 20 μm. Similarly, the above-described varnish for the second layer was applied over the copper foil (thickness of 18 μm, commercially available from Furukawa Circuit Foil Co. Ltd.) to a thickness of 180 μm, and then was dried in a drying furnace at 110 degree C. for 10 minutes and in a drying furnace at 150 degree C. for 10 minutes to form the insulating resin layer with the carrier having a thickness 90 μm, and the obtained two insulating resin layers with the carrier were stacked and the carrier was detached, and then a thermal pressure adhesion process was conducted at 170 degree C. for one hour and at 200 degree C. for two hours to cause a thermal cure, thereby preparing another insulating resin layer (second layer) for evaluation having a thickness of 180 μm.

### Example 4

### 1. Preparation of Resin Varnish

The resin varnish for the first layer and the resin varnish for the second layer were prepared similarly as in Example 1, except that the blending ratios for the resin varnish were selected as follows. The resin varnish for the first layer was prepared to include: 58 wt % of divinylsiloxane-bis benzocyclobutene resin (“CYCLOTENE XUR”); 12 wt % of acrylic-modified polybutadiene rubber (BAC-45); 2 wt % of 2,6-di-(para azide benzal)-4-ethyl cyclohexanone; and 28 wt % of silica (SO-25H). The resin varnish for the second layer was prepared to include: 20 wt % of novolac cyanate resin (Primaset PT-30); 24.7 wt % of biphenyl dimethylene based epoxy resin (NC-3000); 15 wt % of copolymer of phenoxy resin/biphenyl epoxy resin and bisphenol S epoxy resin, terminal part of which has epoxy group (YX-8100H30); 0.1 wt % of imidazole compound (Curezol 1B2PZ); 40 wt % of silica (SO-25H); and 0.2 wt % of epoxy silane coupling agent (A-187).

### 2. Manufacture of Insulating Resin Layer with Carrier

The insulating resin layer with the carrier having a total thickness of the insulating resin layers of 80 μm was manufactured similarly as in Example 1, except that the resin varnish for the first layer and the resin varnish for the second layer obtained as described above were employed.

### 3. Manufacture of Multiple-Layered Printed Wiring Board

The multiple-layered printed wiring board was manufactured similarly as in Example 1, except that the insulating resin layer with the carrier obtained above was employed.

### 4. Manufacture of Insulating Resin Layer for Evaluation

The insulating resin layers for evaluation (first layer, second layer) were manufactured similarly as in Example 1, except that the resin varnish for the first layer and the resin varnish for the second layer obtained above were employed.

### Example 5

### 1. Preparation of Resin Varnish

The resin varnish for the first layer and the resin varnish for the second layer were prepared similarly as in Example 4.

### 2. Manufacture of Insulating Resin Layer with Carrier

The insulating resin layer with the carrier having a total thickness of the insulating resin layers of 100 μm was manufactured similarly as in Example 3, except that the resin varnish for the first layer and the resin varnish for the second layer obtained as described above were employed.

### 3. Manufacture of Multiple-Layered Printed Wiring Board

The multiple-layered printed wiring board was manufactured similarly as in Example 1, except that the insulating resin layer with the carrier obtained above was employed.

### 4. Manufacture of Insulating Resin Layer for Evaluation

The insulating resin layers for evaluation (first layer, second layer) were manufactured similarly as in Example 3, except that the resin varnish for the first layer and the resin varnish for the second layer obtained above were employed.

### Comparative Example 1

### 1. Preparation of Resin Varnish

The resin varnish for the first layer prepared in example 1 was employed.

### 2. Manufacture of Insulating Resin Layer with Carrier

The above-described resin varnish was applied over a copper foil (thickness of 18 μm, commercially available from Furukawa Circuit Foil Co. Ltd.) to a thickness of 160 μm, and then was dried in a drying furnace at 150 degree C. for 10 minutes and in a drying furnace at 170 degree C. for 10 minutes to form the first layer having a thickness 80 μm, thereby presenting the insulating resin layer with the carrier having the insulating resin layer thickness of 80 μm.

### 3. Manufacture of Multiple-Layered Printed Wiring Board

The multiple-layered printed wiring board was manufactured similarly as in Example 1, except that the insulating resin layer with the carrier obtained above was employed.

### 4. Manufacture of Insulating Resin Layer for Evaluation

The above-described resin varnish for the first layer was applied over a copper foil (thickness of 18 μm, commercially available from Furukawa Circuit Foil Co. Ltd.) to a thickness of 160 μm, and then was dried in a drying furnace at 150 degree C. for 10 minutes and in a drying furnace at 170 degree C. for 10 minutes to form the insulating resin layer with the carrier having a thickness 80 μm, and the obtained two insulating resin layers with the carrier were stacked and the carrier was detached, and then a thermal pressure adhesion process was conducted at 170 degree C. for one hour and at 200 degree C. for two hours to cause a thermal cure, thereby preparing an insulating resin layer (first layer) for evaluation having a thickness of 160 μm.

### Comparative Example 2

### 1. Preparation of Resin Varnish

The resin varnish for the second layer prepared in Example 1 was employed.

### 2. Manufacture of the Insulating Resin Layer with the Carrier

The above-described resin varnish was applied over a copper foil (thickness of 18 μm, commercially available from Furukawa Circuit Foil Co. Ltd.) to a thickness of 160 μm, and then was dried in a drying furnace at 110 degree C. for 10 minutes and in a drying furnace at 150 degree C. for 10 minutes to form the first layer having a thickness 80 μm, thereby manufacturing the insulating resin layer with the carrier having the insulating resin layer thickness of 80 μm.

### 3. Manufacture of Multiple-Layered Printed Wiring Board

The multiple-layered printed wiring board was manufactured similarly as in Example 1, except that the insulating resin layer with the carrier obtained above was employed.

### 4. Manufacture of Insulating Resin Layer for Evaluation

The above-described resin varnish for the first layer was applied over a copper foil (thickness of 18 μm, commercially available from Furukawa Circuit Foil Co. Ltd.) to a thickness of 160 μm, and then was dried in a drying furnace at 150 degree C. for 10 minutes and in a drying furnace at 170 degree C. for 10 minutes to form the insulating resin layer with the carrier having a thickness 80 μm, and the obtained two insulating resin layers with the carrier were stacked and the carrier was detached, and then a thermal pressure adhesion process was conducted at 170 degree C. for one hour and at 200 degree C. for two hours to cause a thermal cure, thereby preparing an insulating resin layer (second layer) for evaluation having a thickness of 160 μm.

### Comparative Example 3

### 1. Preparation of Resin Varnish

The resin varnish for the first layer and the resin varnish for the second layer were prepared similarly as in Example 1, except that the blending ratios for the resin varnish were selected as follows. The resin varnish for the first layer was prepared to include: 15 wt % of divinylsiloxane-bis benzocyclobutene resin (“CYCLOTENE XUR”); 45 wt % of acrylic-modified polybutadiene rubber (BAC-45); 2 wt % of 2,6-di-(para azide benzal)-4-ethyl cyclohexanone; and 38 wt % of silica (SO-25H). The resin varnish for the second layer was prepared to include: 37.5 wt % of novolac based cyanate resin (Primaset PT-30); 37 wt % of biphenyl dimethylene based epoxy resin (NC-3000); 15 wt % of copolymer of phenoxy resin/biphenyl epoxy resin and bisphenol S epoxy resin, terminal part of which has epoxy group (YX-8100H30); 0.2 wt % of imidazole compound (Curezol 1B2PZ); 10 wt % of silica (SO-25H); and 0.3 wt % of epoxy silane coupling agent (A-187).

### 2. Manufacture of Insulating Resin Layer with Carrier

The preparation was conducted similarly as in Example 1, except that the resin varnish for the first layer and the resin varnish for the second layer obtained as described above were employed.

### 3. Manufacture of Multiple-Layered Printed Wiring Board

The multiple-layered printed wiring board was manufactured similarly as in Example 1, except that the insulating resin layer with the carrier obtained above was employed.

### 4. Manufacture of Insulating Resin Layer for Evaluation

The insulating resin layers for evaluation (first layer, second layer) were manufactured similarly as in Example 1, except that the resin varnish for the first layer and the resin varnish for the second layer obtained above were employed.

### [Evaluation]

Evaluations for characteristics were conducted by employing the multiple-layered printed wiring boards and the insulating resin layers for evaluation, which were obtained in Examples and Comparative Examples. Results are shown in Table 1.

TABLE 1

| | | | EXAMPLE 1 | EXAMPLE 2 | EXAMPLE 3 | EXAMPLE 4 | EXAMPLE 5 |
|---|---|---|---|---|---|---|---|
| CONTENTS OF | FIRST | CYCLOTENE XUR | 50 | 45 | 50 | 58 | 58 |
| RESIN | LAYER | BAC-45 | 10 | 15 | 10 | 12 | 12 |
| COMPOSITION | | 2,6-di- | 2 | 2 | 2 | 2 | 2 |
| | | (paraazide | | | | | |
| | | benzal)-4-ethyl | | | | | |
| | | cyclohexanone | | | | | |
| | | SO—25H | 38 | 38 | 38 | 28 | 28 |
| | | TOTAL | 100 | 100 | 100 | 100 | 100 |
| | SECOND | PT-30 | 25 | 29.1 | 25 | 20 | 20 |
| | LAYER | NC-3000 | 24.7 | 28.8 | 24.7 | 24.7 | 24.7 |
| | | YX-8100H30 | 10 | 11.8 | 10 | 15 | 15 |
| | | CUREZOL 1B2PZ | 0.1 | 0.1 | 0.1 | 0.1 | 0.1 |
| | | SO—25H | 40 | 30 | 40 | 40 | 40 |
| | | A-187 | 0.2 | 0.2 | 0.2 | 0.2 | 0.2 |
| | | TOTAL | 100 | 100 | 100 | 100 | 100 |
| INSULATING | THICKNESS | FIRST LAYER (μm) | 20 | 20 | 10 | 20 | 10 |
| RESIN LAYER | | SECOND LAYER (μm) | 60 | 60 | 90 | 60 | 90 |
| | | TOTAL (μm) | 80 | 80 | 100 | 80 | 100 |
| EVALUATIONS | FIRST | SPECIFIC | 2.7 | 2.8 | 2.7 | 2.6 | 2.6 |
| | LAYER | DIELECTRIC | | | | | |
| | | CONSTANT (—) | | | | | |
| | | WATER | 0.1 | 0.2 | 0.1 | 0.1 | 0.1 |
| | | ABSORPTION (%) | | | | | |
| | SECOND | LINEAR | 30 | 35 | 30 | 25 | 25 |
| | LAYER | EXPANSION | | | | | |
| | | COEFFICIENT | | | | | |
| | | (ppm/C) | | | | | |
| | | TENSILE | 90 | 80 | 90 | 80 | 80 |
| | | STRENGTH (MPa) | | | | | |
| | | WATER | 1.0 | 1.2 | 1.0 | 0.9 | 0.9 |
| | | ABSORPTION (%) | | | | | |
| | MULTIPLE- | COOLING-HEATING | ◯ | ◯ | ◯ | ◯ | ◯ |
| | LAYERED | CYCLE TEST | | | | | |
| | PRINTING | | | | | | |
| | WIRING | | | | | | |
| | BOARD | | | | | | |

| | | | COMPARATIVE | COMPARATIVE | COMPARATIVE |
|---|---|---|---|---|---|
| | | | EXAMPLE 1 | EXAMPLE 2 | EXAMPLE 3 |
| CONTENTS OF | FIRST | CYCLOTENE XUR | 50 | 0 | 15 |
| RESIN | LAYER | BAC-45 | 10 | 0 | 45 |
| COMPOSITION | | 2,6-di- | 2 | 0 | 2 |
| | | (paraazide | | | |
| | | benzal)-4-ethyl | | | |
| | | cyclohexanone | | | |
| | | SO—25H | 38 | 0 | 38 |
| | | TOTAL | 100 | 0 | 100 |
| | SECOND | PT-30 | 0 | 25 | 37.5 |
| | LAYER | NC-3000 | 0 | 24.7 | 37 |
| | | YX-8100H30 | 0 | 10 | 15 |
| | | CUREZOL 1B2PZ | 0 | 0.1 | 0.2 |
| | | SO—25H | 0 | 40 | 10 |
| | | A-187 | | 0.2 | 0.3 |
| | | TOTAL | 0 | 100 | 100 |
| INSULATING | THICKNESS | FIRST LAYER (μm) | 80 | 0 | 20 |
| RESIN LAYER | | SECOND LAYER (μm) | 0 | 80 | 60 |
| | | TOTAL (μm) | 80 | 80 | 80 |
| EVALUATIONS | FIRST | SPECIFIC | 2.7 | — | 3.3 |
| | LAYER | DIELECTRIC | | | |
| | | CONSTANT (—) | | | |
| | | WATER | 0.1 | — | 0.7 |
| | | ABSORPTION (%) | | | |
| | SECOND | LINEAR | — | 30 | 50 |
| | LAYER | EXPANSION | | | |
| | | COEFFICIENT | | | |
| | | (ppm/C) | | | |
| | | TENSILE | — | 90 | 70 |
| | | STRENGTH (MPa) | | | |
| | | WATER | — | 1.0 | 1.3 |
| | | ABSORPTION (%) | | | |
| | MULTIPLE- | COOLING-HEATING | X | ◯ | X |
| | LAYERED | CYCLE TEST | | | |
| | PRINTING | | | | |
| | WIRING | | | | |
| | BOARD | | | | |

The evaluations were conducted according to the following methods.

### 1. Evaluations for Insulating Resin Layer

(1) Specific dielectric constant: The insulating resin layer with the carrier for evaluation (first layer) and the insulating resin layer with the carrier were employed to measure thereof, based on JIS C 6481 under “A” condition at a frequency of 1 MHz.

(2) Water absorption: The insulating resin layer with the carrier for evaluation (first layer, second layer) and the insulating resin layer with the carrier were employed to measure thereof, based on JIS C 6481 under the conditions of E-24/50+D-24/23.

(3) Linear expansion coefficient: The insulating resin layer with the carrier for evaluation (first layer, second layer) and the insulating resin layer with the carrier were employed to measure thereof for R of 10 degree C., and between 35 degree C. to 85 degree C.

(4) Tensile strength: The insulating resin layer with the carrier for evaluation (second layer) and the insulating resin layer with the carrier were employed to measure thereof in tensile mode under load full scale of 20 kgf at a pulling speed of 5 mm/min.

### 2. Evaluations for Multiple-Layered Printed Wiring Board Cooling-Heating Cycle Test

The multiple-layered printed wiring board was immersed within a solution bath at −65 degree C. for 30 minutes and then was immersed within a solution bath of 125 degrees between 30 minutes, and such procedure was determined as a single cycle, and 1,000 cycles were conducted, and thereafter, a cross section of the resin layer around the chip was observed to confirm an existence of a generation of a crack.

O: no generation of crack
X: crack generated.

Examples 1 to 5 are directed to the insulating resin layers of the present invention composed of the first layer that exhibited the specific dielectric constant at a frequency of 1 MHz of not more than 3.2 and the second layer that exhibited the linear expansion coefficient at an ambient temperature of not more than 40 ppm/degree C., exhibiting enhanced mechanical strengths and improved dielectric characteristics. Further, the multiple-layered printed wiring board of the present invention employing such insulating resin layer exhibited an enhanced reliability in thermal environment and the insulating resin layer having an improved thickness accuracy could be formed. On the contrary, Comparative Example 1 is directed to insulating resin layer composed of only the first layer, which exhibited deteriorated mechanical strengths, and a crack was generated in the cooling-heating cycle test. Comparative Example 2 is directed to the insulating resin layer composed of only the second layer, which exhibited deteriorated water absorption. Further, the multiple-layered printed wiring boards employed these layers exhibited deteriorated characteristics of coupling reliability.

1. An insulating resin layer, which is capable of being employed for forming a multiple-layered printed wiring board via a thermal compression forming process, comprising:
at least one first layer and at least one second layer being stacked,
wherein a specific dielectric constant of said first layer at a frequency of 1 MHz after the thermal compression forming is not more than 3.2, and
wherein a linear expansion coefficient of said second layer at a temperature within a range of from not lower than 35 degree C. to not higher than 85 degree C. after the thermal compression forming is not more than 40 ppm/degree C.

2. The insulating resin layer as set forth in claim 1, wherein a water absorption of said first layer is not more than 0.8 wt %

3. The insulating resin layer as set forth in claim 1, wherein a tensile strength of said second layer is not less than 80 MPa.

4. The insulating resin layer as set forth in claim 1, wherein said first layer contains benzocyclobutene resin and/or a prepolymer thereof.

5. The insulating resin layer as set forth in claim 1, wherein said second layer contains a cyanate resin and/or a prepolymer thereof.

6. An insulating resin layer with a carrier, comprising:
the insulating resin layer as set forth in claim 1; and
a carrier joined to at least one side thereof.

7. A multiple-layered printed wiring board, formed by disposing the insulating resin layer as set forth in claim 1 over at least one side of an internal layer circuit board, and then conducting a thermal compression forming process.

8. A multiple-layered printed wiring board, formed by disposing the insulating resin layer as set forth in claim 6 over at least one side of an internal layer circuit board, and then conducting a thermal compression forming process.
